(19) United States
(12) Patent Application Publication
(10) Pub. No.: US 2024/0152851 A1
(43) Pub. Date: May 9, 2024

(54) WHAT-IF SIMULATION METHOD OF FACTORY SITUATION AND DEVICE THAT IMPLEMENTS SAME

(71) Applicant: VMS Solutions Co. Ltd., Yongin-si (KR)

(72) Inventors: Won Jun LEE, Daejeon (KR); Tae Jun CHOI, Incheon (KR); Goo Hwan CHUNG, Yongin-si (KR); Geon A KIM, Seoul (KR); Jin-Yeong JEONG, Goyang-si (KR)

(73) Assignee: VMS Solutions Co. Ltd., Yongin-si (KR)

(21) Appl. No.: 18/454,551

(22) Filed: Aug. 23, 2023

(30) Foreign Application Priority Data
Nov. 7, 2022 (KR) 10-2022-0147122

(51) Int. Cl. G06Q 10/067; G06F 30/20; G06Q 10/0639

(52) U.S. Cl. CPC G06Q 10/067; G06F 30/20; G06Q 10/06393

(57) ABSTRACT

Provided is a device for performing simulation for work schedule of a factory includes an experiment design module for generating experiment design data by selecting one or more factors from a plurality of factors included in reference information as target factors, and setting levels of the selected target factors, the reference information being an input value to a model that serves as a target of a what-if simulation experiment, and an experiment execution module for outputting an experiment execution result by executing the what-if simulation experiment for the model in parallel by using an executor including a plurality of execution engines based on the experiment design data.

### TECHNICAL FIELD

The present disclosure relates to a what-if simulation method of a factory situation and a device that implements the same, and more particularly, to a method and a device for effectively determining optimal experiment results by automating a what-if simulation that extracts performance indicators while changing factors of a model.

### BACKGROUND

Factories, for example, semiconductor manufacturing plants, are among the most sophisticated man-made systems, and generally consist of hundreds or thousands of expensive pieces of equipment connected to an automated resource processing system. Establishing an optimal work schedule in a factory consisting of such a large number of pieces of equipment can significantly improve factory productivity.

However, in order to arrange work schedules for many pieces of equipment that were deployed in a factory, previous systems relied on heuristic solutions based on parameters tuned by human managers, such as experts, but this method has drawbacks that it requires human intervention each time to set up a work schedule in the factory, which can limit the efficiency of factory operations.

In particular, it is clear that the heuristic solutions by human managers as described above have limitations in establishing a dispatching strategy for selecting and ordering available tasks performed at each workplace, and there is an urgent need to develop and distribute alternative methods that can compensate for this.

Accordingly, a method of predicting the results of a scenario in advance by performing a simulation on the scenario for the work schedule of a factory has been used. However, in performing a what-if simulation that extracts performance indicators while changing factors of a scenario or simulation model, there is no automated tool and there exists inconvenience that humans have to enter scenarios or factors one by one manually.

### SUMMARY

Therefore, it is one object of the present disclosure to provide a method that can automate and facilitate the process of extracting performance indicators while changing the levels of factors of the reference information of a model that serves as the target of a what-if simulation for the work schedules of a factory.

In addition, it is another object of the present disclosure to facilitate the process of effectively determining an optimal experiment result through a what-if simulation for the work schedules of a factory and based on this, establishing a dispatching strategy for the work schedules of an actual factory.

However, the objects to be achieved by the present disclosure are not limited to those mentioned above, and may include objects that have not been mentioned but can be clearly understood by those of ordinary skill in the art to which the present disclosure pertains from the description below.

In the following, specific means for achieving the objects of the present disclosure will be described.

A device for performing simulation for work schedule of a factory in accordance with one embodiment of the present disclosure, comprises an experiment design module for generating experiment design data by selecting one or more factors from a plurality of factors included in reference information as target factors, and setting levels of the selected target factors, the reference information being an input value to a model that serves as a target of a what-if simulation experiment, and an experiment execution module for outputting an execution result by executing the what-if simulation for the model in parallel by using an executor comprising a plurality of execution engines based on the experiment design data.

In the device described above, setting the levels of the target factors comprises selecting types of the levels, and receiving inputs for level values for the types of the levels selected.

In the device described above, the types of the levels comprise at least one of a List type that allows values specified directly by a manager to be defined as the level values, a Range type that allows a minimum value (min), a maximum value (max), and an increment to be set, and a Distribution Sampling type that randomly extracts level values from a specified range.

In the device described above, the experiment execution result of the experiment execution module comprises performance indicators (KPIs).

In the device described above, the experiment execution module further comprises a custom output processing module, and the experiment execution result comprises custom output data defined by a manager, wherein the custom output data is extracted by the custom output processing module.

In the device described above, the model is selected by receiving a selection by a manager via a user interface of the device for designing the what-if simulation experiment.

In the device described above, a data analysis module for analyzing and presenting the experiment execution result to a manager is further included.

In the device described above, analyzing the experiment execution result in the data analysis module comprises performing correlation coefficient analysis and sensitivity analysis between the performance indicators and the target factors.

A system for performing simulation of work schedule of a factory in accordance with one embodiment of the present disclosure, comprises a client device for designing and executing a what-if simulation experiment, a simulation management server including a management module for managing an application for the what-if simulation experiment on the client device, and an external DB for storing data on the what-if simulation experiment, wherein the client device comprises an experiment design module for generating experiment design data by selecting one or more factors from a plurality of factors included in reference information as target factors, and setting levels of the selected target factors, the reference information being an input value to a model that serves as a target of a what-if simulation experiment, and an experiment execution module for outputting an experiment execution result by executing the what-if simulation experiment for the model by using an executor based on the experiment design data, and wherein the simulation management server further comprises a simulation module for executing the what-if simulation experiment, and if the client device transmits an experiment execution request to the simulation management server, the what-if simulation experiment by the experiment execution module is not executed.

A method for performing simulation of work schedule of a factory in accordance with one embodiment of the present disclosure, comprises selecting one or more factors from a plurality of factors included in reference information that is an input value to a model that serves as a target of a what-if simulation experiment as target factors, generating experiment design data by setting levels of the selected target factors, and outputting an experiment execution result by executing the what-if simulation for the model in parallel by using an experiment executor (or module) including a plurality of simulation engines based on the experiment design data.

As described above, there are the following effects according to the present disclosure.

First, the design of experiments can be made easy by making it possible to automate the process of extracting performance indicators while changing the levels of factors of the reference information of a model that serves as a target of a what-if simulation for the work schedules of a factory.

Second, it can help users in making decisions about factory situations, such as establishing a dispatching strategy for the work schedules of the factory, based on the experiment results obtained by executing what-if simulations.

Third, since what-if simulations for each of a plurality of input data sets can be executed in parallel, it allows efficient use of the processing capabilities and resources of the client device and the simulation management server compared to the existing method in which human managers manually enter input data one by one and conduct simulations, and thus, the processing speed is significantly faster, the amount of human labor can be minimized, and the possible occurrences of errors due to human intervention can be reduced.

Fourth, the design of experiments can be facilitated by allowing a manager to intuitively create and edit the input data to experiments via a separate user interface.

However, the effects that can be obtained with the present disclosure are not limited to those mentioned above, and other effects that have not been mentioned will be clearly understood by those of ordinary skill in the art to which the present disclosure pertains from the description below.

### BRIEF DESCRIPTION OF THE DRAWINGS

As the following drawings accompanying the present specification illustrate preferred embodiments of the present disclosure and serve to help further understand the technical idea of the present disclosure together with the detailed description of the present disclosure, the present disclosure should not be construed as being limited to those described in such drawings.

FIG. 1 is a diagram schematically showing a system for what-if simulating work schedules of a factory in accordance with one embodiment of the present disclosure;

FIGS. 2 and 3 are example views of user interfaces for entering input data for designing a what-if simulation in accordance with one embodiment of the present disclosure;

FIG. 4 is an example view of a factor editor for selecting factors to be changed out of input data for a what-if simulation and selecting levels of the factors in accordance with one embodiment of the present disclosure;

FIG. 5 is an example view of a factor editor for selecting factors to be changed out of input data for a what-if simulation and selecting levels of the factors in accordance with another embodiment of the present disclosure;

FIG. 6 is an example view of an output data editor for editing output data of a what-if simulation in accordance with one embodiment of the present disclosure;

FIG. 7 is an example view of an experiment design editor for the design of a what-if simulation in accordance with one embodiment of the present disclosure;

FIG. 8 is a diagram schematically showing the structure of an experiment execution module in accordance with one embodiment of the present disclosure; and

FIG. 9 is a flowchart of a method for performing a simulation for work schedules of a factory in accordance with one embodiment of the present disclosure.

### DETAILED DESCRIPTION OF THE PREFERRED EMBODIMENTS

Hereinafter, embodiments that enable those of ordinary skill in the art to which the present disclosure pertains to readily implement the present disclosure will be described in detail with reference to the accompanying drawings. However, the present disclosure may be embodied in a number of different forms and is not limited to the examples described herein. Further, in describing the operating principle of the preferred embodiments of the present disclosure in detail, if it is determined that a detailed description of related known functions or configurations may unnecessarily obscure the subject matter of the present disclosure, the detailed description thereof will be omitted.

In addition, the same reference numerals will be used for parts that serve for similar functions and actions throughout the drawings. Throughout the specification, when a certain part is said to be connected to or above/below another part, this includes not only the case of being directly connected or above/below, but also the case of being indirectly connected or above/below with yet another component interposed therebetween.

Furthermore, when a part is said to “include” a component throughout the specification, this does not mean to exclude other components but means that it may further include other components unless specifically stated to the contrary.

Terms such as “first” and “second” may be used to describe various components, but these components should not be limited by such terms. That is, the terms are used only for the purpose of distinguishing one component from another. For example, a first component may be named a second component, and similarly, a second component may be named a first component, without departing from the scope of the present disclosure. The descriptions “and/or” and “/” include any combination of a plurality of related listed items or any one of a plurality of related listed items.

In addition, unless specifically stated otherwise, “singular” expressions are used herein to include one or more entities. Lastly, as used herein, “or” means a non-exclusive “or” unless specifically stated otherwise.

Further, as the terms used in the present disclosure, common terms that are currently widely used as much as possible while taking into account the functions in the present disclosure have been selected, but this may vary depending on the intentions of technicians working in the field, judicial precedents, the emergence of new technology, and the like. In addition, there are also terms arbitrarily selected by the applicant in particular cases, in which case the meaning will be described in detail in the relevant description of the disclosure. Therefore, the terms used in the present disclosure should be defined based on the meanings of the terms and the overall contents of the present disclosure, rather than simple names of the terms.

Overview of a System for Simulating Work Schedules of a Factory

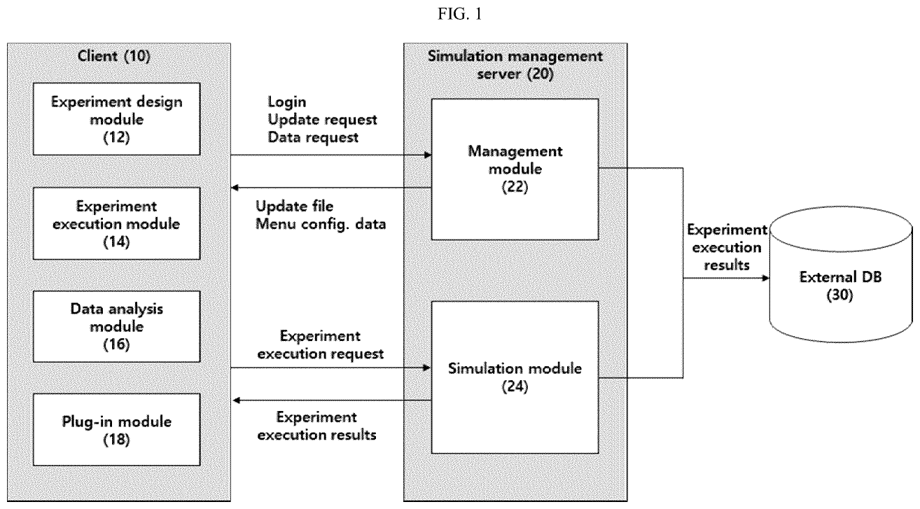

FIG. 1 is a diagram schematically showing a system for simulating work schedules of a factory in accordance with one embodiment of the present disclosure.

Referring to FIG. 1, the system for simulating work schedules of a factory may include a client device 10, a simulation management server 20, and an external database (DB) 30.

The client device 10 may be one or more computing devices of a manager or other users who manage and supervise a factory, and may be, for example, various devices such as a server, a PC, a mobile phone, a tablet, a laptop computer, and a PDA. The client device 10 may include an experiment design module 12, an experiment execution module 14, a data analysis module 16, and a plug-in module 18, and these modules may be software modules implemented by executing computer-executable instructions by the processor of a manager device, or may be configured as separate hardware modules or a combination of these, but are not limited thereto.

The experiment design module 12 may select one or more factors in which the manager has an interest in the experiment results out of a plurality of factors included in reference information that is an input value to a model that serves as a target of the what-if simulation experiment as target factors, generate experiment design data by allowing the levels of the selected target factors to be changed and inputted, and through this, enable various designs for the what-if simulation experiment. Here, the model may be a virtual factory environment created on a computer based on factory situation information such as the equipment, workpieces, and setup times of an actual factory, and may be configured to output an output value that is the result of the simulation experiment when the reference information that serves as the input value is inputted to the model. According to the present disclosure, a plurality of simulations may be included in one what-if simulation experiment, and there may be a sequence between the simulations. Describing the process of designing a what-if simulation experiment, first, a manager may select a base model that serves as the target of the what-if simulation experiment via a user interface of the client device 10.

After selecting the base model, the manager may select one or more factors of interest (i.e., to apply changes) out of several factors of the reference information that is an input value to the corresponding model as independent variables, and define levels of the selected factors. The reference information of the model may include at least one of a data table and a global variable. If necessary, the manager may go through a process of newly creating factors and levels of the reference information of the model. In addition, via the experiment design module 12, the manager may define (i.e., generate or select) output values, for example, performance indicators (KPIs), as dependent variables for evaluating the results of the what-if simulation experiment to be performed on the model via the user interface of the client device 10. A performance indicator (KPI) is represented in a single number or any object (time, character, etc.) by refining experiment execution results, and refining the experiment results may include not only displaying the results of the what-if simulation experiment as they are but also displaying various mathematical expressions (sum, count, average, mean, min, max, std, etc.) from the experiment results in a combined form. As such, the manager may design a what-if simulation experiment and generate experiment design data by selecting a model, and independent variables (factors of the reference information to be changed) and dependent variables (performance indicators) of the model via the experiment design module 12.

In another embodiment, if the manager wants to use the experiment design data of what-if simulation experiments that were conducted previously, for example, target factors, performance indicators, and the like, instead of selecting target factors, performance indicators, or the like, the manger may load and reuse values predefined in existing experiments as well. To this end, the experiment design data used in each experiment may be implemented as a separate data structure and provided in the form of a user interface so as to be selectable by the manger.

In addition, according to the present disclosure, since each experiment has a data structure, respectively, as such, it has the advantage that not only the comparison of results between individual simulations but also the comparison of experiment units (i.e., between experiments) including a plurality of simulations is possible. Such a comparison may be performed by, but is not limited to, the data analysis module 16.

The experiment execution module 14 may generate input data to be inputted to an executor, execute the executor, and output an experiment execution result based on the experiment design data of the what-if simulation experiment whose model, independent/dependent variables, and the like are defined via the experiment design module 12. At this time, the experiment execution module 14 may go through a process of generating input data for the what-if simulation experiment through a preprocessing process for the input values inputted by the manager to the model. According to another embodiment, the input data in the preprocessing process may be generated based further on experiment design data as well as historical engine output data, which are result values outputted in previously performed simulations or experiments.

The experiment execution module 14 includes a plurality of simulation engines for performing individual simulations within a designed experiment. The simulation engines may be called in plurality at the same time by the experiment execution module and executed in parallel. The simulation engines may receive individual experiment design data as input, be executed, and output simulation results.

In addition, the client device 10 may include a plurality of experiment execution modules 14, and all or some of the plurality of experiment execution modules 14 may be executed in parallel at the same time if the computational resources of the client device 10 allow.

Meanwhile, the input data may include a plurality of input data sets, and in this case, what-if simulation experiments for each of the plurality of input data sets may be executed in parallel via a plurality of execution engines of the executor based on the processing capabilities and resources of the client device 10. Since such parallel experiment execution makes it possible to efficiently use the processing capabilities and resources of the client device 10 and the simulation management server 20 compared to the existing method in which humans manually enter input data one by one and conduct simulation experiments, it has the effect that the processing speed is significantly faster, the input of human labor can be minimized, and the possible occurrences of errors due to human intervention can be reduced.

Further, according to one embodiment, the experiment execution module 14 may include a custom output processing module. Additional custom output data defined by the manager can be extracted and outputted as the experiment execution results via the custom output processing module. As one example, the custom output processing module may collect and extract data when one model finishes execution or when the entire experiment is finished by arbitrarily creating an output schema that is not predefined in the model by the manager. For example, if it is set to record only the input time and completion time of workpieces as the output of a particular model, cycle time information can be made to be outputted as custom output data via the custom output processing module if the manager wants to output the cycle time (completion time−input time) information. In addition, the custom output processing module may configure an output schema consisting of two columns including Lot_ID (workpiece ID) and Cycle_Time, and may generate custom output data by obtaining the Cycle_Time value, i.e., the value of completion time−input time at the end of each simulation run and putting it into the corresponding output schema. As such, the experiment execution module 14 may include performance indicators and/or custom output data as the experiment execution results.

The data analysis module 16 serves to query and analyze the experiment execution results of the what-if simulation experiment. As a non-limiting example, the experiment execution results of each what-if simulation experiment include at least the factor values (e.g., one or more factors and the level of each factor) inputted for the experiment execution and the performance indicator (KPI) values that are the experiment results, and such experiment execution results may be displayed in the form of a report. Further, interim experiment results may be updated periodically (e.g., at 10 s, 30 s, 60 s intervals, etc.) even in the middle of the experiment execution by setting the auto-refresh interval via the client device 10 by the manager, and an expected end time (or remaining experiment time) may be predicted and outputted by the data analysis module 16.

According to one embodiment, the data analysis module 16 may display a chart that allows comprehensive checking of correlation coefficients between the factor values and the performance indicator (KPI) values included in the experiment execution results of each what-if simulation experiment. As one example, the chart may include a correlation matrix in which rows are factor values and columns are performance indicator (KPI) values, and a plot graph displaying a plot between the factor values and the performance indicator values that are high in correlation in the correlation matrix. Sensitivity analysis between the factor values and the performance indicators may be performed via the plot graph. As one example, the sensitivity analysis may be about the extent to which the performance indicators change accordingly when the factor values change or whether changes occur in the performance indicators when the factor values are greater than equal to or less than equal to which value (i.e., thresholds of the factor values), and is not limited on the specific contents.

The plug-in module 18 may include one or more plug-in modules that extend functionality so that the model can be executed in a variety of ways, such as optimizing the model and the input data to the model through what-if simulation experiments, facilitating the editing of each factor of the input data, or enabling input of new factor values, performance indicators, etc.

As one non-limiting example, the plug-in module 18 may include a weight optimizer module that optimizes the weights of preset factors used in scheduling through reinforcement learning via artificial neural networks at the time of dispatching the model for the what-if simulation experiment.

In addition, the plug-in module 18 may include a parameter exploring policy gradient (PEPG) optimizer module that supports simulation argument optimization by using a PEPG, and through this, may perform the function of repetitively performing experiments to discover factors that optimize the performance indicators through a kind of reinforcement learning when the user specifies the factors and the performance indicators (KPIs).

Referring to FIG. 1, the simulation management server 20 may include a management module 22 and a simulation module 24. The management module 22 allows for sending and receiving data related to logins, updates, user interface (UI) menu configurations, and the like when executing a factory simulation application on the client device 10 to perform the what-if simulation experiment. As one non-limiting example, the management module 22 may receive a login request of the client device 10 via the simulation management server 20 and check the identity of the manager, transmit update files, menu configuration data, and the like to the client device by an update request and a data request, and through this, serves to maintain and manage the factory simulation application installed on the client device 10.

The simulation module 24 of the simulation management server 20 is a module for executing what-if simulation experiments on behalf of the client device 10. As described above, the client device 10 may perform a series of processes ranging from designing and executing a what-if simulation experiment to analyzing experiment result data by including the experiment design module 12, the experiment execution module 14, the data analysis module 16, and the plug-in module 18. However, in some cases, due to limitations in processing capabilities or resources of the client device 10, there may be cases in which it is difficult to directly execute the what-if simulation experiment on the client device 10 or the experiment execution speed is slow. Accordingly, the what-if simulation experiment may be executed instead in the simulation management server 20. As one example, when the client device 10 transmits an execution request and/or experiment design data for a what-if simulation experiment to the simulation management server 20, the simulation management server 20 may execute the corresponding experiment via the simulation module 24 and transmit the experiment execution result to the client device 10. In this case, the experiment execution module of the client device 10 will not directly execute the what-if simulation experiment.

The external DB 30 may record and store the experiment execution results of the what-if simulation experiment generated by the client device 10 and/or the simulation management server 20. In addition, the external DB 30 may store not only the experiment execution results but also various data such as information on a large number of client devices 10, models for simulation, and reference information of each model.

Method for Entering Input Data for Designing a What-if Simulation Experiment

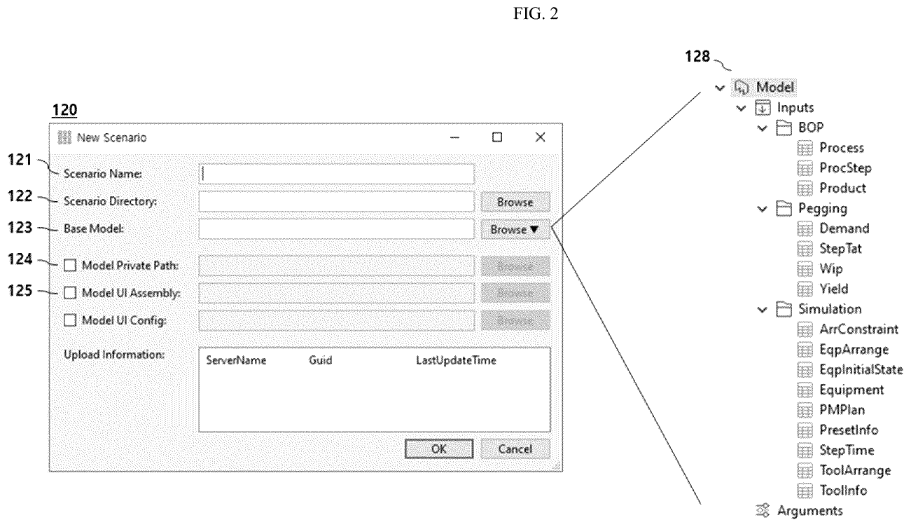

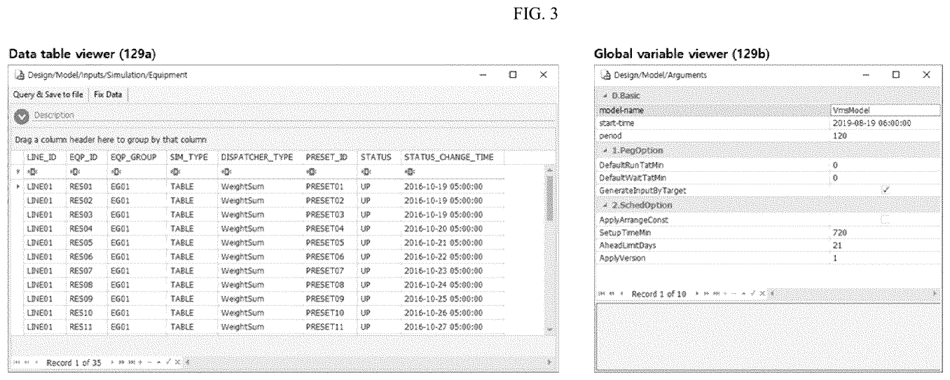

FIGS. 2 and 3 are example views of user interfaces for entering input values for designing a what-if simulation experiment in accordance with one embodiment of the present disclosure. As will be described in detail below, input values may be received from the manager via a user interface displayed on the client device 10 in the process of designing such an experiment.

Referring first to FIG. 2, the user interface of the factory simulation application running on the client device 10 may display a window 120 for creating a new what-if simulation experiment (New Scenario). The window 120 may include a Scenario Name entry 121 where the name of an experiment can be entered, a Scenario Directory entry 122 where the directory for the experiment can be set, and a Model entry 123 from which a model for the experiment can be selected. In addition, a model path entry 124 that allows specifying the path of an assembly required to execute the experiment using the selected model, and a UI path entry 125 that allows specifying the path of a corresponding UI if there is a customized UI for the selected model may be included. A pop-up window 128 that allows selecting a model is displayed when the browse button located next to the Model entry 123 is selected, and the manager may select one model from a model tree displayed on the pop-up window 128.

Moreover, referring to FIG. 3, when the manager selects a model that serves as the target of a what-if simulation via the pop-up window 128, a user interface that allows editing a data table and global variables, which are reference information of the input values to the selected model, may be displayed. As one non-limiting example, the user interface may include a data table viewer 129a that allows viewing and editing data tables and a global variable viewer 129b that allows viewing and editing global variables, and the reference information of the model can be edited via these viewers. However, the method of editing the reference information may be modified in a variety of ways, and is not limited thereto. The illustration in FIG. 3 shows an example of the data table viewer when a model called Equipment is selected out of the models and an example of the global variable viewer when the manager selects the Arguments path in the pop-up window 128.

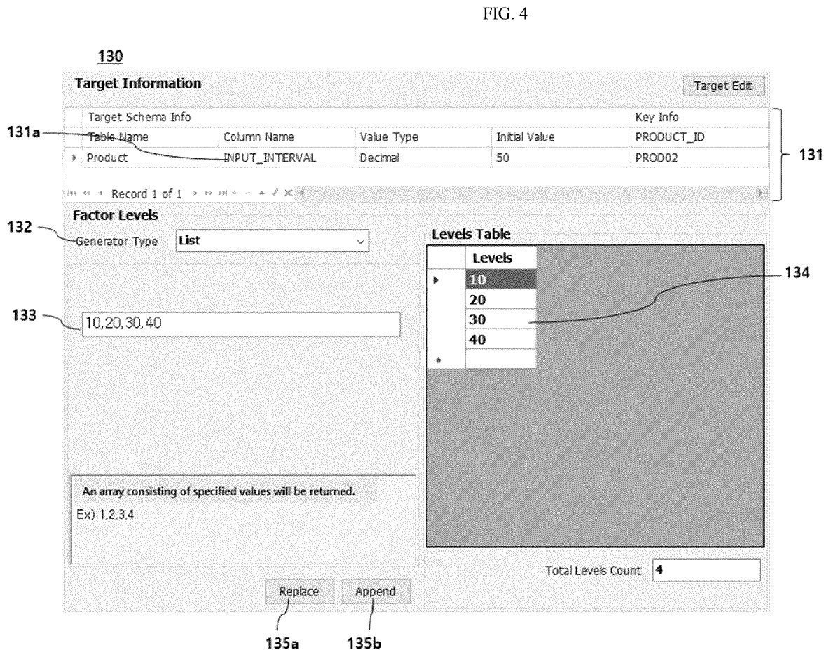

FIG. 4 is an example view of a factor editor for selecting factors to be changed out of input values for a what-if simulation experiment and selecting levels of the factors in accordance with one embodiment of the present disclosure.

Referring to FIG. 4, target factors to conduct an experiment with while changing their levels may be selected out of the reference information of the model that will serve as the target of the what-if simulation experiment via the factor editor. In a non-limiting example, the reference information of the model may include factors in the data table and the global variable table, and one or more of these factors may be selected as target factors, and how to change the levels of the selected target factors may be registered. The example of FIG. 4 shows defining the target factors and the levels intended to execute a what-if simulation experiment on the values of the Product data table in the model. It is about the case where a factor called INPUT_INTERVAL in the Product data table has been selected as the target factor 131a, and a level setting window 130 that allows setting a level for the selected target factor 131a may be displayed. The level setting window 130 may include a target factor information display part 131 for the target factor 131a, a level type input part 132, a level value input part 133, and a level value display part 134. The List type has been selected in the level type input part 132 in the example of FIG. 4, and the List type corresponds to a type that causes a value specified directly by the manager to be defined as the level value. In addition, there is a Range type that allows setting a minimum value (min), a maximum value (max), and an increment, a Distribution Sampling type that allows extracting level values randomly from a specified distribution may be selected, and other types can also be set. For example, a type that performs a function of loading values generated from an external program or script or level values from an editing application program such as Excel, a type that performs a copy & paste function using the clipboard, or the like may be set.

As a specific example, the List type, the Range type, and the Distribution Sampling type may be applied when the target factor is an integer or real number, the List type and the Interval Time type (a value indicating a time interval) may be applied when the target factor is a date, and only the List type may be applied when the target factor is a string. In the example of FIG. 4, after selecting the List type, the manager has entered specific level values of 10, 20, 30, and 40 into the level value input part 133, and as a result, the level values (10, 20, 30, and 40) entered by the manager may be displayed on the level value display part 134. In addition, the manager may replace or add the level types and values by selecting a Replace button 135a and an Append button 135b. As can be seen from the example above, the level value may be a number or any object (time, string, etc.).

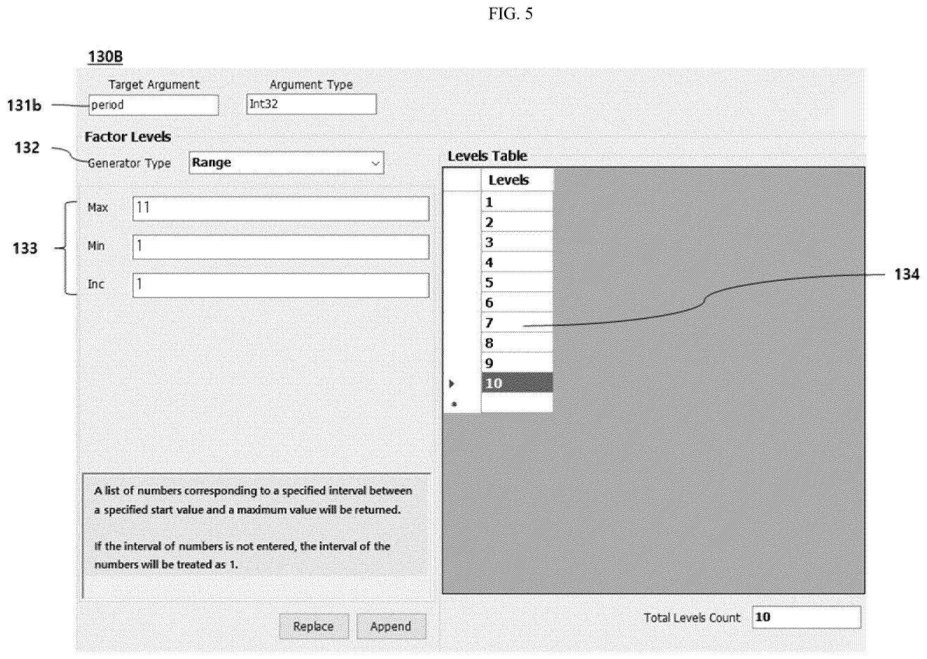

FIG. 5 is an example view of a factor editor for selecting factors to be changed out of input values for a what-if simulation experiment and selecting levels of the factors in accordance with another embodiment of the present disclosure.

Referring to FIG. 5, one example of a factor editor in the case where period has been selected from the Input Arguments in the global variable viewer as the target factor 131b is shown. Further, if the Range type is selected in the level type input part 132 for the target factor, entries into which a minimum value (Min), a maximum value (Max), and an increment (Inc) can be entered in the level value input part 133 may be displayed. And, if the manager enters 1 as the minimum value (Min), 11 as the maximum value (Max), and 1 as the increment (Inc) in the level value display part 134, the levels of the target factors to be used as input values when executing the what-if simulation experiment may be displayed.

As such, according to one embodiment of the present disclosure, there arises an effect of facilitating experiment design by allowing the manager to intuitively create and edit the target factors and their levels of the input values for the simulation experiment via a separate user interface called the factor editor.

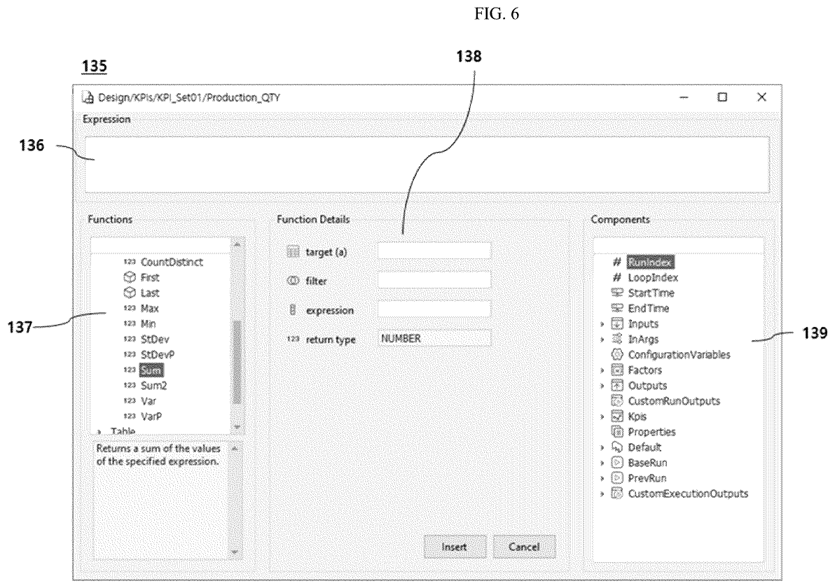

FIG. 6 is an example view of an output data editor for editing output data of a what-if simulation experiment in accordance with one embodiment of the present disclosure.

Referring to FIG. 6, an output data editor 135 is for editing the output data of the what-if simulation experiment, and the output data at this time may include at least one of performance indicators (KPIs) for each what-if simulation experiment and additional custom output data defined by the manager. Here, the performance indicators (KPIs) and the custom output data are a set of indices for evaluating the results of the what-if simulation experiment, and the results of the what-if simulation experiment are evaluated by executing the model according to a combination of the factors. In the example of FIG. 6, the output data editor 135 may include a performance indicator calculation formula editing part 136, a function selection part 137, a function editing part 138, and a candidate model data display part 139 for displaying model data that can be inputted.

Via the performance indicator calculation formula editing part 136, the manager may input a calculation formula to be used for calculating the performance indicators (or custom output data). In one example, an expression for calculating the performance indicators (or custom output data) may be inputted by utilizing one or more factors of the input data or output data of the model used in the what-if simulation experiment.

Preset functions may be selected in the function selection part 137, and for example, functions such as four arithmetic operations, exponentials, logarithms, trigonometric functions, type conversion, and table aggregation (first, last, sum, avg, std, count) are available, and specific numerical values of the selected functions or the like may be edited and inputted via the function editing part 138. For example, a calculation formula such as [Sum(OutPuts.ProductCycleTimeTable, “CycleTimeSec”)/Count(Inputs.ProductTable, “ProductID”, “PROD01”)−0.05] may be edited by selecting a function such as sum, count, etc., using the performance indicator calculation formula editing part 136, the function selection part 137, the function editing part 138, and the candidate model data display part 139 and selecting one or more factors of the model (OutPuts.ProductCycleTimeTable, Inputs.ProductTable, etc.). In addition, if it is not a numerical value, a single value can be inputted as a calculation formula.

As such, according to one embodiment of the present disclosure, there arises an effect of facilitating experiment design by allowing the manager to intuitively create and edit the output data to be outputted as the results of the simulation experiment via a separate user interface called the output data editor.

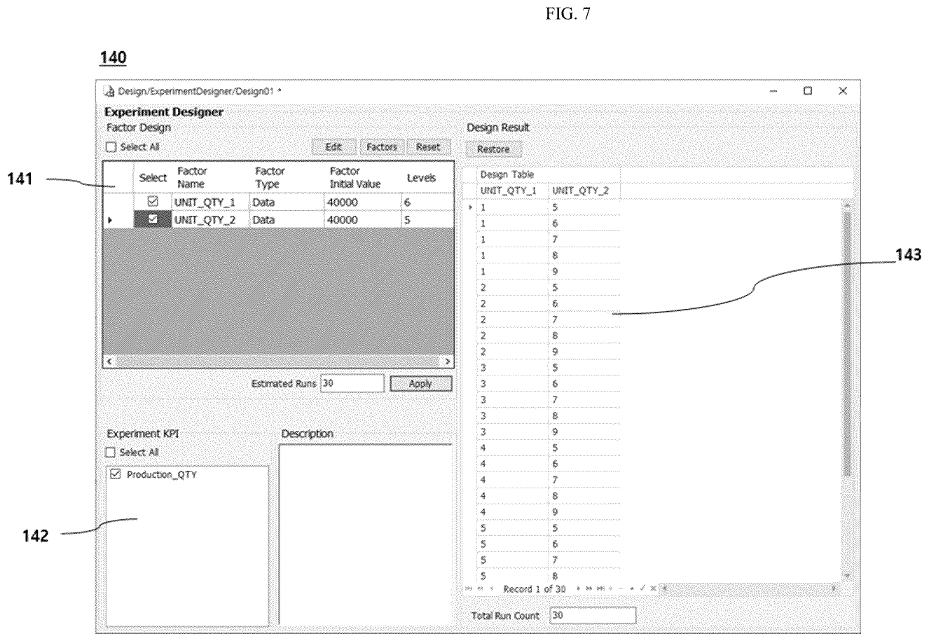

FIG. 7 is an example view of an experiment design editor for the design of a what-if simulation experiment in accordance with one embodiment of the present disclosure.

Referring to FIG. 7, an experiment design editor 140 may allow the manager to design a what-if simulation experiment by using one or more factors and performance indicators (KPIs) inputted. The experiment design editor 140 may include a factor designation part 141, a performance indicator designation part 142, and a preview window 143. The example of FIG. 7 shows a case where two factors UNIT_QTY_1 and UNIT_QTY_2 are designated in the factor designation part 141 and Production_QTY is designated in the performance indicator designation part 142. In this case, since the factor UNIT_QTY_1 has 6 levels and the factor UNIT_QTY_2 has 5 levels, a total of 6×5=30 experiment runs is set, an experiment design obtained by combining each level of the factors UNIT_QTY_1 and UNIT_QTY_2 is displayed in the preview window 143, and the output data may be outputted with the value designated in Production_QTY after selecting the Apply button and executing the experiment.

Experiment design data for the what-if simulation experiment can be inputted efficiently from the manager via the user interface of the client device 10 in accordance with one embodiment of the present disclosure described above, and accordingly, design for a number of experiments can be carried out in an intuitive way with only simple input from the point of view of the manager, and thus, there arises an effect of being able to greatly simplify the process of experiment design and at the same time reduce errors in the experiment design process.

On the other hand, in another embodiment, if the manager wants to use the experiment design data of what-if simulation experiments or simulations that were conducted previously, for example, target factors, levels of the target factors, performance indicators, and the like, instead of selecting target factors, performance indicators, or the like, the manger may load and reuse values predefined in existing experiments or simulations as well. This may be referred to as an iterative experiment design, and one iterative experiment may be configured to include a plurality of unit experiments or iterations. In addition, one unit experiment or iteration may include a plurality of what-if simulations. The number of simulations included in one unit experiment may be specified in advance. Loading predefined values may include not only loading the values (factors, performance indicators, etc.) for the immediately preceding unit experiment or individual simulations within the experiment but also loading the values for several previously performed unit experiments or individual simulations within the experiments. Such an iterative experiment design may be set to repeat a pre-specified number of times or terminate when a user-specified condition is reached. An example of the user-specified condition may include a condition such as terminating an experiment when one of the performance indicators is greater than or equal to a particular value, but is not limited thereto. For such an iterative experiment design, the experiment design data used in each experiment (or simulation) may be implemented as a separate data structure and provided in the form of a user interface so as to be selectable by the manger, although not shown.

Experiment Execution Module

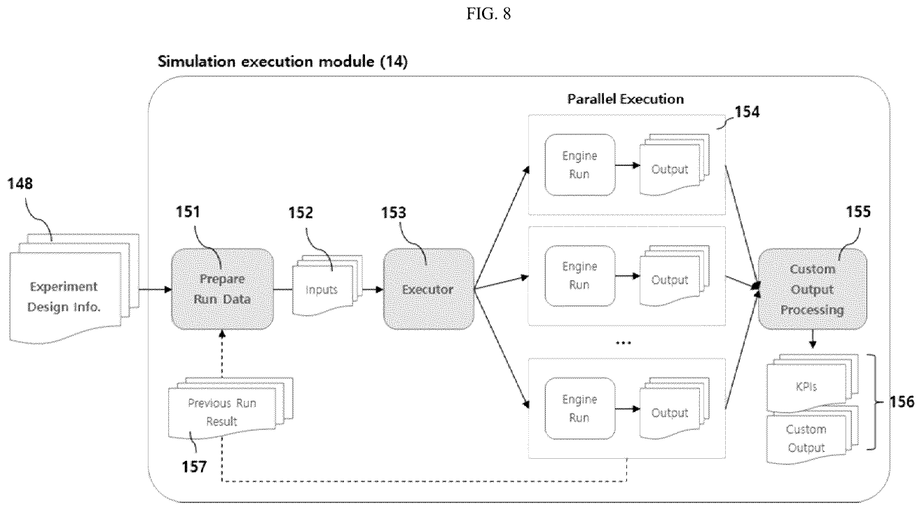

FIG. 8 is a diagram schematically showing the structure of an experiment execution module in accordance with one embodiment of the present disclosure.

Referring to FIG. 8, the experiment execution module 14 may receive experiment design data 148 from the experiment design module 12, preprocess them, generate input data 152, and then execute experiments based on the input data 152, thereby generating execution results 156.

Described specifically, the experiment execution module 14 may include a preprocessing module 151, an executor 153, and a custom output processor 155. The preprocessing module 151 may receive the experiment design data 148 from the experiment design module 12, convert them into a form suitable for executing experiments in the executor 153, and generate input data 152. The preprocessing here may include, for example, substituting input values entered by the manager into the model with factor values.

The executor 153 may receive input data for the what-if simulation experiment from the preprocessing module 151, and input them into the model and execute it via one or more execution engines included in the executor 153, thereby generating engine output data. According to one embodiment, if a plurality of input data sets for each of a plurality of what-if simulation experiments is received, the executor 153 may execute the what-if simulation experiments in parallel by assigning and entering the input data in parallel to each (or at least some) of the plurality of execution engines. Since such parallel experiment execution makes it possible to efficiently use the processing capabilities and resources of the client device 10 and the simulation management server 20 compared to the existing method in which humans manually enter input data one by one and conduct simulation experiments, it has the effect that the processing speed is significantly faster, the input of human labor can be minimized, and the possible occurrences of errors due to human intervention can be reduced.

Further, the experiment execution module 14 may include a custom output processor 155. From the engine output data for the what-if simulation experiment conducted by entering the input data to the model by each of the plurality of experiment engines via the custom output processor 155, output data, i.e., performance indicators (KPIs) and custom output data, can be extracted and outputted as the experiment execution results.

According to another embodiment of the present disclosure, historical engine output data 157 for previously performed simulations or experiments may be provided to the preprocessing module 151 for some of the what-if simulation experiments, and the preprocessing module 151 may generate the input data 152 based on the historical engine output data 157 and the experiment design data 148.

That is, according to the present disclosure, a plurality of simulations may be included within one experiment, and the results of a previous simulation (the results of the immediately preceding simulation or the results of one or more previously performed simulations) can be used as input to the next simulation in situations where there is a sequence among the simulations. Alternatively, the results of a previous experiment may be used as input to the next experiment in situations where each experiment has a sequence. Therefore, the historical engine output data 157 in the present disclosure may refer to the result data of a previously executed simulation out of a plurality of simulations within an experiment, or may also refer to the result data of a previously performed experiment out of a plurality of experiments. The manager can choose whether to utilize the historical engine output data 157 via the user interface, and if it is chosen to utilize the historical engine output data 157, the results of previous experiments can be reflected in the current experiment, and thus, there arises an effect of enabling an experiment design of a dependent nature.

Method for Performing Simulations for Work Schedules of a Factory

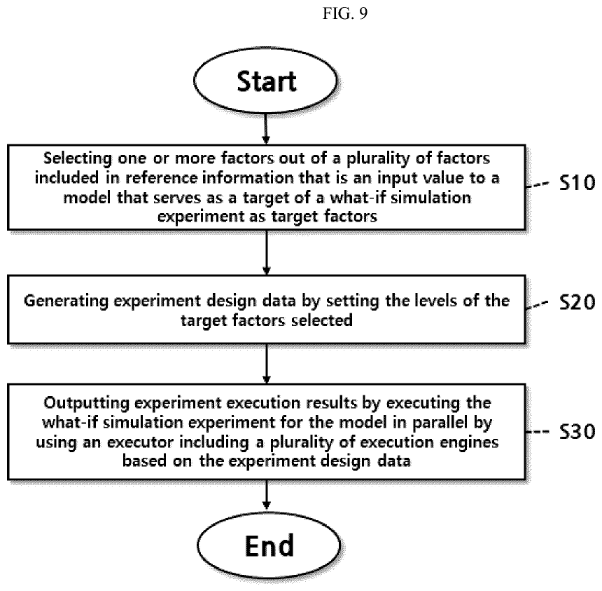

FIG. 9 is a flowchart of a method for performing a simulation for work schedules of a factory in accordance with one embodiment of the present disclosure. Such a simulation method for work schedules of a factory may be performed by a processor or one or more modules implemented by the processor of a client device and/or a simulation management server of a manager.

Referring to FIG. 9, first, in step S10, one or more factors out of a plurality of factors included in reference information that is an input value to a model that serves as a target of a what-if simulation experiment may be selected as target factors. The model may include at least reference information serving as an input value, and an output value that is the simulation experiment result. Further, the model may be selected by receiving a selection by the manager via the user interface of the client device for designing the what-if simulation experiment.

In step S20, experiment design data may be generated by setting the levels of the target factors selected in step S10. In this case, setting the levels of the target factors may include selecting the types of levels and receiving inputs for level values for the types of levels selected. In addition, the types of the levels may include at least one of a List type that allows the values specified directly by the manager to be defined as the level values, a Range type that allows a minimum value (min), a maximum value (max), and an increment to be set, and a Distribution Sampling type that randomly extracts level values from a specified range.

In step S30, experiment execution results may be outputted by executing the what-if simulation experiment for the model in parallel by using an executor including a plurality of execution engines based on the experiment design data. In this case, the experiment execution results of the experiment execution module may include performance indicators (KPIs) and/or custom output data defined by the manager, and the custom output data may be extracted by a custom output processing module included in the experiment execution module.

Computer-Readable Recording Medium

It will be apparent that each step or operation of the method in accordance with the embodiments of the present disclosure may be performed by a computer including one or more processors according to the execution of a computer program stored in a computer readable recording medium.

The computer-executable instructions stored on the recording medium described above may be implemented via a computer program programmed to perform each corresponding step, and such a computer program may be stored on a computer-readable recording medium and may be executed by a processor. The computer-readable recording medium may be a non-transitory readable medium. In this case, the non-transitory readable medium refers to a medium that stores data semi-permanently and is readable by a machine, rather than a medium that stores data for a short period of time, such as a register, cache, memory, or the like. Specifically, programs for performing the various methods described above may be stored and provided in a non-transitory readable medium such as a non-volatile memory and the like, including semiconductor memory devices such as erasable programmable read-only memory (EPROM), electrically erasable programmable read-only memory (EEPROM), and flash memory devices, magnetic disks such as internal hard disks and removable disks, opto-magnetic disks, and CD-ROM and DVD-ROM disks.

Methods in accordance with various examples disclosed herein may be included and provided in a computer program product. The computer program product may be distributed in the form of a machine-readable storage medium (e.g., compact disc read-only memory (CD-ROM)) or online via an application store (e.g., Play Store™). In the case of online distribution, at least part of the computer program product may be stored at least temporarily or generated tentatively on a storage medium such as memory of a manufacturer's server, an application store server, or a relay server.

As described above, those of ordinary skill in the art to which the present disclosure pertains will understand that the present disclosure may be embodied in other specific forms without changing its technical idea or essential features. Therefore, it should be understood that the embodiments described above are illustrative in all respects and not intended to be limiting. The scope of the present disclosure is indicated by the following claims rather than by the detailed description, and all changes or variations derived from the meaning and scope of the claims and equivalent concepts should be construed as falling within the scope of the present disclosure.

The features and advantages described herein are not exhaustive, and in particular, many additional features and advantages will become apparent to those of ordinary skill in the art upon consideration of the drawings, specification, and claims. Moreover, it should be noted that the language used herein has been chosen primarily for ease of reading and for the purpose of teaching, and may not be chosen to depict or limit the subject matter of the present disclosure.

The foregoing description of embodiments of the present disclosure has been presented for purposes of illustration. This is not intended to limit the present disclosure to the exact form disclosed or to make it without omission. Those of ordinary skill in the art can appreciate that many modifications and variations are possible in light of the above disclosure.

Therefore, the scope of the present disclosure is not limited by the detailed description, but rather by any claims of the application based thereon. Accordingly, the disclosure of the embodiments of the present disclosure is illustrative and does not limit the scope of the present disclosure set forth in the claims below.

### DESCRIPTION OF REFERENCE NUMERALS AND SYMBOLS

10: Client device
12: Experiment design module
14: Experiment execution module
16: Data analysis module
18: Plug-in module
20: Simulation management server
22: Management module
24: Simulation module
30: External DB

What is claimed is:

1. A device for performing simulation for work schedule of a factory, comprising:
an experiment design module for generating experiment design data by selecting one or more factors from a plurality of factors included in reference information as target factors, and setting levels of the selected target factors, the reference information being an input value to a model that serves as a target of a what-if simulation experiment; and
an experiment execution module for outputting an experiment execution result by executing the what-if simulation experiment for the model in parallel by using an executor comprising a plurality of execution engines based on the experiment design data.

2. The device of claim 1, wherein setting the levels of the target factors comprises:
selecting types of the levels; and
receiving an input for level values for the types of the levels selected.

3. The device of claim 2, wherein the types of the levels comprise at least one of:
a List type that allows values specified directly by a manager to be defined as the level values,
a Range type that allows a minimum value (min), a maximum value (max), and an increment to be set, and
a Distribution Sampling type that randomly extracts level values from a specified range.

4. The device of claim 1, wherein the experiment execution result of the experiment execution module comprises performance indicators (KPIs).

5. The device of claim 4, wherein the experiment execution module further comprises a custom output processing module, and the experiment execution result comprises custom output data defined by a manager, wherein the custom output data is extracted by the custom output processing module.

6. The device of claim 1, wherein the model is selected by receiving a selection by a manager via a user interface of the device for designing the what-if simulation experiment.

7. The device of claim 1, further comprising:
a data analysis module for analyzing and presenting the experiment execution result to a manager.

8. The device of claim 7, wherein analyzing the experiment execution result in the data analysis module comprises performing correlation coefficient analysis and sensitivity analysis between the performance indicators and the target factors.

9. A system for performing simulation of work schedule of a factory, comprising:
a client device for designing and executing a what-if simulation experiment;
a simulation management server including a management module for managing an application for the what-if simulation experiment on the client device; and
an external DB for storing data for the what-if simulation experiment,
wherein the client device comprises:
an experiment design module for generating experiment design data by selecting one or more factors from a plurality of factors included in reference information as target factors, and setting levels of the selected target factors, the reference information being an input value to a model that serves as a target of a what-if simulation experiment; and
an experiment execution module for outputting an experiment execution result by executing the what-if simulation experiment for the model by using an executor based on the experiment design data, and
wherein the simulation management server further comprises a simulation module for executing the what-if simulation experiment, and
if the client device transmits an experiment execution request to the simulation management server, the what-if simulation experiment by the experiment execution module is not executed.

10. A method for performing simulation of work schedule of a factory, comprising:
selecting one or more factors from a plurality of factors included in reference information that is an input value to a model that serves as a target of a what-if simulation experiment as target factors;
generating experiment design data by setting levels of the selected target factors; and
outputting an experiment execution result by executing the what-if simulation experiment for the model in parallel by using an executor comprising a plurality of execution engines based on the experiment design data.
